(19) United States
(12) Patent Application Publication
(10) Pub. No.: US 2007/0233954 A1
(43) Pub. Date: Oct. 4, 2007

(54) System and Method for Interfacing to a Media Card Related Application and Technical Field

(75) Inventor: Neil Morrow, San Jose, CA (US)

Correspondence Address: GROSSMAN, TUCKER, PERREAULT & PFLEGER, PLLC, 55 SOUTH COMMERICAL STREET, MANCHESTER, NH, 03101, US

(73) Assignee: O2MICRO, INC., Santa Clara, CA (US)

(21) Appl. No.: 11/566,471

(22) Filed: Dec. 4, 2006

Related U.S. Application Data
(60) Provisional application No. 60/742,960, filed on Dec. 6, 2005.

(51) Int. Cl. G06F 12/00; H05K 7/10

(52) U.S. Cl. 711/115; 710/301

(57) ABSTRACT

An apparatus includes a media card reader implemented on an integrated circuit. The media card reader includes at least one register that stores data representative of a media card being inserted into a media card socket. The register is accessible, via a first path, by a secure digital (SD) driver for determining compatibility with the SD driver. If the inserted media card is incompatible with the SD driver, the register is accessed via a second path by a multimedia card (MMC) driver for determining compatibility with the MMC driver.

### RELATED APPLICATION AND TECHNICAL FIELD

This application is related to the following U.S. application, of common assignee, from which priority is claimed, and the contents of which are incorporated herein in their entirety by reference: “System and Method for Enhancing a Standard Secure Digital Bus Interface,” U.S. Provisional Patent Application Ser. No. 60/742,960, filed Dec. 6, 2005.

This disclosure relates to media cards and, more particularly, to determining if a media card is compatible with a software driver.

### BACKGROUND

Devices such as media cards provide, for example, memory for portable electronic devices such as digital cameras, digital video camcorders, audio players, cellular telephones, and/or personal digital assistants (PDAs). One type of media card is a Multimedia (MMC) card that may store several Giga-bytes (GB) of data (e.g., compressed music, compressed video, high-resolution images, etc.). Secure Digital (SD) cards are another type of media card that may also store several GB of data. Additionally, SD cards typically allow the stored data to be write-protected. A third type of media card is a Secure Digital Input Output (SDIO) card that may provide data transferring capabilities along with the storage capabilities of an SD card. For example, some SDIO cards may be connected to networks by using the Institute of Electrical and Electronics Engineers (IEEE) standard for wireless local area network interoperability (802.11b), also know as WiFi.

To store and retrieve data, each of these three types of media cards may be inserted into a common socket that may be connected to a computer system. A software driver includes instructions that allow the computer system to communicate with peripheral devices such as media cards. By communicating with the media card, the computer system and applications executed on the computer system may interact (e.g., store date, retrieve data, etc.) with the inserted media card. For example, a Secure Digital Bus Driver produced by Microsoft Inc. of Redmond, Wash. follows the SDIO Standard Host Controller Specification 1.0 in order to support SD and SDIO cards. However, other types of media cards such as MMC cards are not supported by the Microsoft SD bus driver.

### SUMMARY OF THE DISCLOSURE

In accordance with an aspect of the disclosure, an apparatus includes a media card reader implemented on an integrated circuit. The media card reader includes at least one register that stores data representative of a media card being inserted into a media card socket. The register is accessible, via a first path, by a secure digital (SD) driver for determining compatibility with the SD driver. If the inserted media card is incompatible with the SD driver, the register is accessed via a second path by a multimedia card (MMC) driver for determining compatibility with the MMC driver.

In accordance with another aspect of the disclosure, an apparatus includes media card controller circuitry implemented on an integrated circuit. The media card controller circuitry includes a media card detector that identifies, absent input from software, a type of media card inserted into a media card socket. The media card controller circuitry also includes a register that stores data representative of the media card type. The register is accessible, via a first path, by a secure digital (SD) driver. The register is also accessible via a second path by a multimedia card (MMC) driver.

In accordance with another aspect of the disclosure, a method includes storing data in a register that represents a media card being inserted into a socket. The method also includes accessing the register with a first software driver via a first path. The method also includes determining if a secure digital (SD) driver is compatible with the media card. The method also includes, if incompatible with the SD driver, accessing the register with a multimedia driver (MMC) via a second path, different from the first path. The method also includes determining if the MMC driver is compatible with the media card.

In accordance with another aspect of the disclosure, an article includes a storage medium storing instructions that when executed by a machine result in the following operations: storing data in a register that represents a media card being inserted into a socket; accessing the register with a first driver via a first path; determining if a secure digital (SD) driver is compatible with the media card; if incompatible with the SD driver, accessing the register with a multimedia driver (MMC) via a second path, different from the first path; and determining if the MMC driver is compatible with the media card.

Additional advantages and aspects of the present disclosure will become readily apparent to those skilled in the art from the following detailed description, wherein embodiments of the present invention are shown and described, simply by way of illustration of the best mode contemplated for practicing the present invention. As will be described, the present disclosure is capable of other and different embodiments, and its several details are susceptible of modification in various obvious respects, all without departing from the spirit of the present disclosure. Accordingly, the drawings and description are to be regarded as illustrative in nature, and not as limitative.

### BRIEF DESCRIPTION OF THE DRAWINGS

FIG. 1 is a diagrammatic view of a portable computer system and a media card for use in the portable computer system.

FIG. 2 is a block diagram that represents the inserted media card and portions of the computer system shown in FIG. 1.

FIG. 3 is a block diagram that represents one exemplary embodiment of the media card controller circuitry shown in FIG. 2.

FIG. 4 is a flowchart that represents operations of the media card controller circuitry shown in FIG. 3.

FIG. 5 is a block diagram that represents another exemplary embodiment of the media card controller circuitry shown in FIG. 2.

FIG. 6 is a flowchart that represents operations of the media card controller circuitry shown in FIG. 5.

### DETAILED DESCRIPTION OF THE EMBODIMENTS

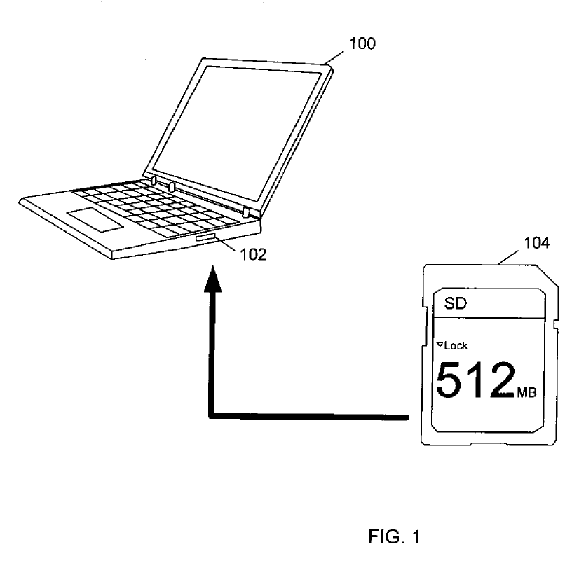

Referring to FIG. 1, an exemplary computer system 100 may include a socket 102 for receiving a media card 104. While computer system 100 is receptive to media card 104, other electronic devices may also include one or more sockets for receiving the media card. For example, media card 104 may be inserted into a socket of a digital camera, a digital video camcorder, an audio player, a cellular telephone, a personal digital assistant (PDA) and/or other type of portable electronic device. Media card 104 may include a data storage capability that may provide for relatively fast storing and accessing of a considerable amount of data (e.g., several GBs). For example, media card 104 may be an SD card, an SDIO card and/or a MMC card.

Computer system 100 may execute one or more applications that may access media card 104. For example, an application (e.g., Microsoft Outlook™, Microsoft Excel™, etc.) may store data on and/or retrieve data from media card 104. However, prior to using media card 104, computer system 100 may need to establish an interface with the media card. Accordingly, computer system 100 may identify an appropriate software driver for interfacing with media card 104. For example, if media card 104 is a SD card, computer system 100 may identify and utilize a standard SD software driver that resides in the memory of the computer system. Alternatively, if media card 104 is an MMC card, computer system 100 may identify an MMC software driver to communicate with the media card. By identifying and utilizing an appropriate software driver, computer system 100 may be capable of, for example, storing data or accessing stored data on an SD card, an SDIO card, and/or an MMC card.

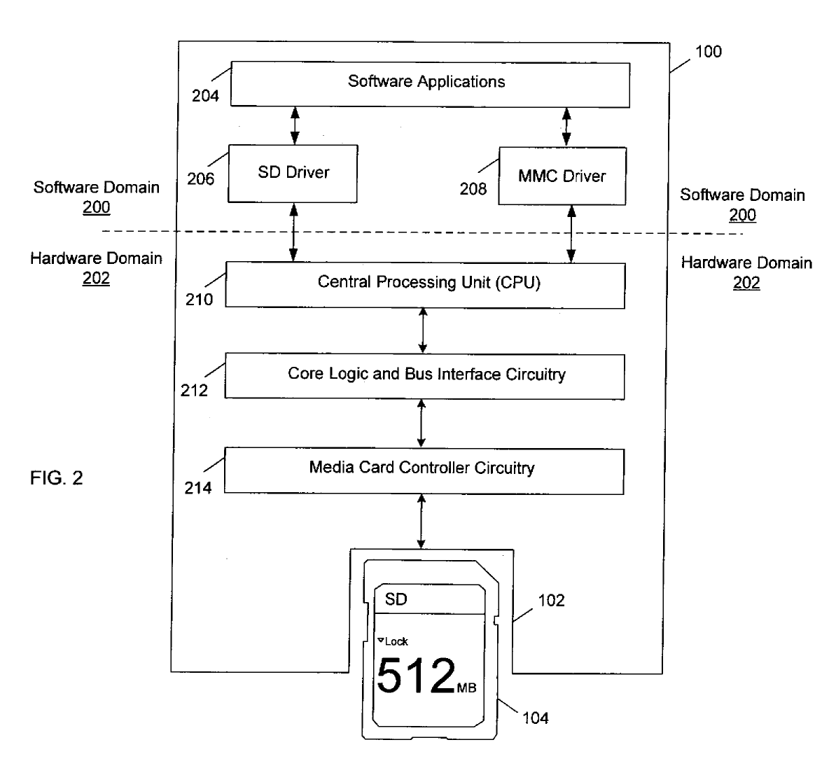

Referring to FIG. 2, a block diagram of portable computer system 100 is shown. Media card 104 is shown inserted into socket 102. To illustrate hardware and software components, computer system 100 may be divided into a software domain 200 and a hardware domain 202. Software domain 200 may include software applications 204, an exemplary SD driver 206 and an exemplary MMC driver 208. Additionally, software domain 200 may include other software components. For example, an operating system (not shown) and/or additional software drivers (e.g., an SDIO driver) may be included in software domain 200.

Hardware domain 202 may include socket 102 that may be capable of receiving typical media cards such as SD cards, MMC cards, and/or and SDIO cards. In this illustrative example, media card 104 may be inserted into socket 102. Hardware domain 202 may also include a central processing unit (CPU) 210, Core Logic and Bus Interface Circuitry 212, and media card controller circuitry 214. Computer system 100 may also include other components in hardware domain 202. For example, one or more memories (e.g., random access memory (RAM), read-only memory (ROM), static RAM (SRAM), dynamic RAM (DRAM), etc.) and/or one or more storage devices (e.g., a hard drive, CD-ROM, etc.) may be included in hardware domain 202.

In general, the information stored on media card 104 may be used by software applications 204 (e.g., executed by CPU 210). For example, media card 104 may provide additional storage along with other functionality such as network connectivity to a local area network (LAN), wide area network (WAN), a personal area network (PAN), or other similar type of networking scheme.

Typically, software applications 204 may be incapable of directly communicating with media card 104. To form a communication link, software applications 204 may use one or more software drivers capable of communicating with media card 104. For example, if media card 104 is an SD card, software applications 204 may utilize SD driver 206 to interface with media card 104. Alternatively, if media card 104 is an MMC card, software applications 204 may utilize MMC driver 208 to interface with media card 104.

Prior to utilizing SD driver 206, MMC driver 208 and/or other types of software drivers (e.g., SDIO driver), the type (e.g., SD card, MMC card, SDIO card, etc.) of media card 104 may be identified. To identify the type of media card, media card controller circuitry 214 may include logical circuitry and/or state machine circuitry that may communicate with media card 104. By collecting and analyzing information from media card 104, the media card may be identified, for example, as an SD card or an MMC card. In this embodiment, CPU 210 and Core Logic and Bus Interface circuitry 212 allow SD driver 206 and MMC driver 208 to access the information gathered by media card controller circuitry 214 and to assist in the card type identification.

As mentioned above, the type of media card 104 may be identified via SD driver 206 and/or MMC driver 208. Alternatively, in some embodiments, media card controller circuitry 214 may independently identify the card type of media card 104. Once identified, media card controller circuitry 214 may signal the appropriate driver (e.g., SD driver 206, MMC driver 208, etc.) to establish an interface with media card 104. Once communicating with the appropriate driver, software applications 204 may utilize the capabilities of media card 104.

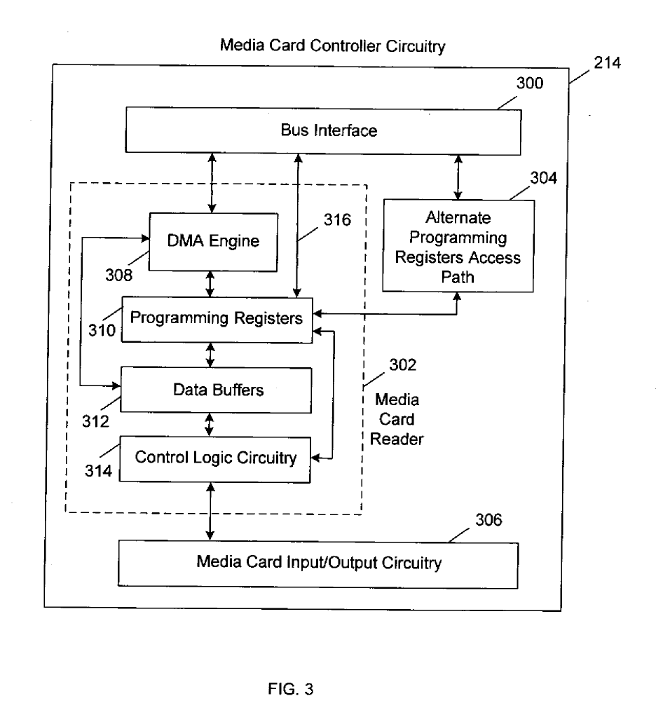

Referring to FIG. 3, one exemplary embodiment of media card controller circuitry 214 is shown. In this embodiment, media card controller circuitry 214 may include a bus interface 300, a media card reader 302, an alternate programming registers access path 304 and media card input/output circuitry 306. In this embodiment, media card reader 302 may include a direct memory access (DMA) engine 308, one or more programming registers 310, one or more data buffers 312, and control logic circuitry 314.

Bus interface 300 may allow data to be passed between media card controller circuitry 214 and Core Logic and Bus Interface Circuitry 212 (shown in FIG. 2). For example, bus interface 300 may implement a high speed connection such as a peripheral component interconnect (PCI) interface for data communications. To exchange data with inserted media card 104, control logic circuitry 314 may include a state machine that may be directed by content stored in programming registers 310 to communicate with the media card. To exchange data, control logic circuitry 314 may connect to buffers and/or drivers included in media card input/output circuitry 306 that may be compatible with the media card specifications (e.g., SD specifications, MMC specifications, etc.). DMA engine 308 and programming registers 310 may be used to read data from and write data to data buffers 312.

When media card 104 is inserted into socket 102, an indication signal may be generated and provided to media card reader 302. In one embodiment, data may be stored in programming registers 310 to indicate that media card 104 has been inserted. For example, data may be stored in programming registers 310 when power is provided to the inserted media card. Similarly, an indication signal may be generated when media card 104 is removed from socket 102. Upon the insertion indication data being stored in programming registers 310, SD driver 206 (shown in FIG. 2) may be alerted that a media card has been inserted into socket 102. SD driver 206 may then attempt to determine if media card 104 is an SD card.

For this determination, SD driver 206 may attempt to communicate with media card 104 via media card controller circuitry 214. For example, SD driver 206 may provide one or more commands to programming registers 310 that may be executed with assistance from media card 104. SD driver 206 may provide these commands via a path 316 between bus interface 300 and programming registers 310. Path 316 may be accessed by SD driver 206 with an address that may have been assigned to one or more of programming registers 310. By using this address, SD driver 206 may provide data to (e.g., commands) and/or retrieve data from (e.g., a response from media card 104) programming registers 310 over dedicated path 316. For example, a command may be provided over path 316 from SD driver 206 to programming registers 310. By passing the command to media card 104 for execution, data (e.g., a confirmation response, vendor information, etc.) may be provided back to media card reader 302 from the media card. SD driver 206 may then use path 316 (via the address assigned to programming registers 310) to check for an appropriate response. By analyzing the response, SD driver 206 may determine information associated with media card 104 (e.g., card type, etc.).

If SD driver 206 is unable to identify media card 104 as an SD card, MMC driver 208 may attempt to identify the media card as an MMC card. To attempt this determination, MMC driver 208 may provide one or more commands and/or data to programming register 310. The commands and/or data may then be used by and/or in conjunction with media card 104 to generate a response. To access programming registers 310, MMC driver 208 may use a second address that may be assigned to the programming registers. The address used by MMC driver 208 may be unique compared to the address associated with path 316 and used by SD driver 206. As shown in the figure, use of the second address is illustrated by alternate programming registers access path 304 that may be located between bus interface 300 and programming registers 310. Similar to SD driver 206, data returned by media card 104 may be used by MMC driver 208 to identify information associated with the media card (e.g., card type, etc.).

MMC driver 208 may initiate determining if media card 104 may be an MMC card based one or more events. For example, if SD driver 206 halts attempting to identify media card 104, MMC driver 208 may initiate identification operations. In another scenario, MMC driver 208 may initiate identification operations when SD driver 206 initiates removing power from media card 104. In still another scenario, MMC driver 208 may initiate identification operations after a period of time in which media card 104 may be inactive.

If either SD driver 206 or MMC driver 208 identifies media card 104 as being compatible with an SD card format or an MMC card format, the appropriate driver may provide software applications 204 access to the media card. For example, if SD driver 206 determines that media card 104 is an SD card, software applications 204 may access data stored in the media card. Alternatively, if SD driver 206 does not identify media card 104 as being compatible and MMC driver 208 identifies the media card as an MMC card, software applications 204 may access the data storage capabilities of the media card via the MMC driver.

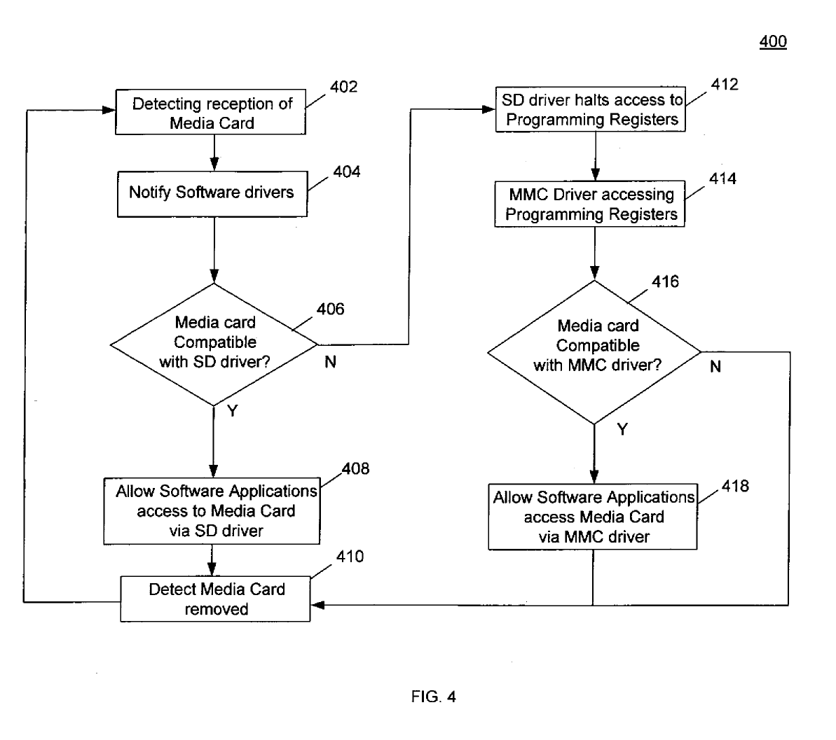

FIG. 4 presents a flowchart 400 that includes some of the operations of media card controller circuitry 214. For example, some operations may include detecting 402 a media card being inserted into a socket such as socket 102. Media card insertion may involve notifying media card controller circuitry 214. For example, a status register that may be included in programming registers 310 may be activated. An interrupt event for CPU 210 may be generated in combination or alternatively to the activating of the status register. Along with notifying components in hardware domain 202, components in software domain 200 may be notified of the media card insertion. For example, operations may include notifying 404 one or more software drivers that may be compatible with the inserted media card. As previously mentioned, in one embodiment SD driver 206 and MMC driver 208 may be notified of the insertion of the media card. For notification, each driver may check data stored in programming registers 310. SD driver 206 may access programming registers 310 with the address associated with path 316. MMC driver 208 may access programming registers 310 with the address associated with alternate programming register access path 304. MMC driver 208 may also be notified to the media card insertion by a separate status register (not shown) that may be included in alternate programming registers access path 304.

Once notified, SD driver 206 determines 406 if the inserted media card is compatible with the SD driver. To determine compatibility (e.g., media card type, media card capabilities, etc.), SD driver 206 may provide data to and/or receive data from the inserted media card. To exchange information with the media card, SD driver 206 may use programming registers 310 to control the data exchange.

If determined that the inserted media card is compatible with SD driver 206, operations may then include allowing 408 software applications 204 to access the inserted media card through the SD driver. Typically, access to the inserted media card continues until the media card controller circuitry detects 410 that the card has been removed from the socket connection. Upon detecting the removal, operations of the media card controller circuitry includes returning to detect 402 the insertion of another (or the same) media card.

If determined that the inserted media card is incompatible with SD driver 206, operations may include the SD driver halting 412 access to programming registers 310. By halting access, data may no longer be exchanged between the inserted media card and the SD driver. Operations may also include MMC driver 208 accessing 414 programming registers 310 to determine if SD driver 206 has halted communications. To access the programming registers, MMC driver 208 may use the address associated with path 316. However, typically MMC driver 208 uses the address associated with alternate programming register access path 304.

To determine if SD driver 206 has halted communications, MMC driver 208 may read data stored in one or more of programming registers 310. For example, data may be read that represents if power is being applied to the inserted media card or if power delivery has been removed from the media card. Data read from programming registers 310 may also represent the last communication command used by SD driver 206 to exchange data with the inserted media card. Based upon the last command from SD driver 206, MMC driver 208 may determine if SD driver 206 has halted communications with media card 104. Also, a halt in communication may be detected from data received by programming registers 310 from media card 104. In one embodiment, a halt in communication may be indicated if some data provided to programming registers 310 remains constant of a period of time. For example, if data provided from media card 104 remains unchanged for a period of time (e.g., 2 seconds), after media card 104 has been inserted for a period of time (e.g., 4 seconds), may be indicative that SD driver 206 has halted interactions with the media card.

Various types of data may be provided to programming registers 310 that may be used to indicate that SD driver 206 has halted communications with media card 104. As mentioned this data may include data representative of power delivery and/or the last command provided by SD driver 206. Other data may include one or more parameters (e.g., bus width) or characteristics (e.g., operating speed, memory capacity, etc.) associated with media card 104. Other techniques may also be utilized to indicate a halt in communications. For example, no response (or a non-responsive acknowledgement) received after a period of time (e.g., 2 seconds) following power delivery may be indicative of SD driver 206 halting interactions with media card 104.

Once SD driver 206 has halted access to programming registers 310 and MMC driver 208 has accessed the programming registers, some operations may include the MMC driver determining 416 if media card 104 is compatible with the MMC driver. To determine compatibility, MMC driver 208 may determine the card type and/or the capabilities of media card 104 by using programming register 310 for controlling data exchanges between the media card and the MMC driver. If determined that media card 104 is compatible with MMC driver 208, some operations may include allowing 418 software applications 204 access to media card 104 via the MMC driver. Typically, access is allowed until media card controller circuitry 214 detects 410 that media card 104 has been removed from socket 102. Upon detecting the removal, media card controller circuitry 214 returns to waiting for detecting 402 the insertion of another (or the same) media card. Similarly, if media card 104 is incompatible with MMC driver 208, media card controller circuitry 214 waits to detect the removal 410 of the media card and then returns to detect 402 the insertion of a media card. To determine if media card 104 has been removed, SD driver 206 and/or MMC driver 208 may be notified by communicating with programming registers 310. For example, by exchanging data with programming registers 310 via path 316, SD driver 206 may determine if media card 104 has been removed. Similarly, MMC driver 208 may communicate with programming registers 310 via alternate programming access path 304 to determine if media card 104 has been removed. In another exemplary technique, MMC driver 208 may communicate with a dedicated status register (not shown) to determine if media card 104 has been removed.

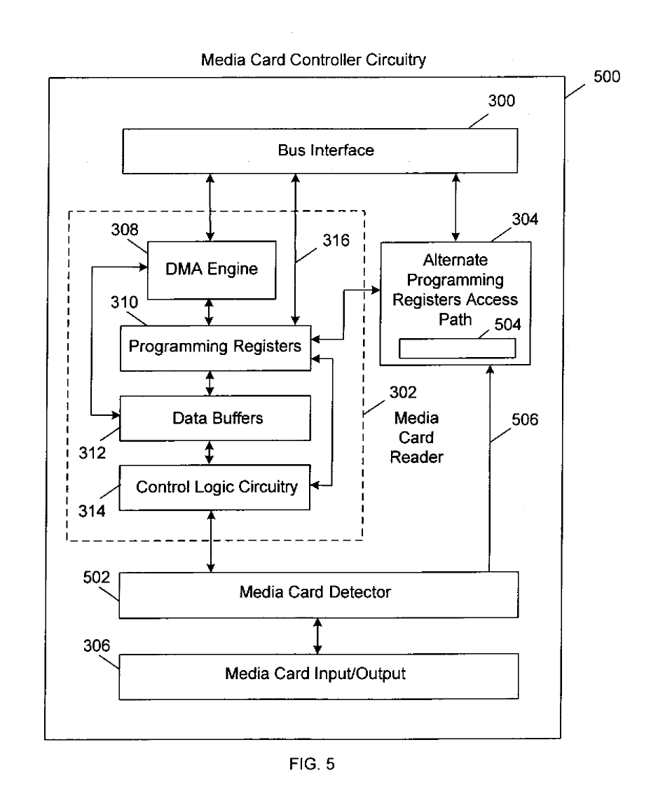

Referring to FIG. 5, another embodiment of media card controller circuitry 500 is shown. Similar to media card controller circuitry 214 (shown in FIG. 3), media card controller 500 includes bus interface 300, media card reader 302, alternate programming registers access path 304 and media card input/output 306. Additionally, media card controller circuitry 500 includes a media card detector 502. Also, similar to media card controller circuitry 214 (shown in FIG. 3), media card reader 302 includes DMA engine 308, programming registers 310, data buffers 312 and control logic circuitry 314.

Media card detector 502 may determine if inserted media card 104 may be compatible with SD driver 206 and/or MMC driver 208. Media card detector 502 may make the determinations in hardware domain 202, and input and/or analysis from components (e.g., SD driver 206, MMC driver 208, etc.) in software domain 200 may be substantially reduced or removed. By using a hardware implementation, compatibility may be determined relatively quickly in comparison to using SD driver 206 and/or MMC driver 208 as discussed above in conjunction with FIGS. 3 and 4.

Media card detector 502 may include hardware to implement logic and/or state machine techniques for exchanging data with an inserted media card (e.g., media card 104). By exchanging data, media card detector 502 may determine the type and/or capabilities of the inserted media card. Media card detector 502 may also control the delivery of power to the inserted media card, for example, the closing of a power switch (not shown) may be controlled to provide power to socket 102. Additionally, media card detector 502 may mask the insertion of media card 104 from media card reader 302. In particular, media card detector 502 may block data exchanges between the inserted media card 104 and programming registers 310.

To identify the compatibility of the media card 104, media card detector 502 may locally store information representative of the capabilities supported by SD driver 206, MMC driver 208 and other drivers (e.g., SDIO drivers) that may be included in software domain 200. If media card 104 is determined to be compatible with SD driver 206, media card detector 502 may alert programming registers 310 that media card 104 has been inserted into socket connector 102. Additionally, media card detector 502 may then pass control of inserted media card 104 to SD driver 206. Alternatively, if media card detector 502 determines that inserted media card 104 is compatible with MMC driver 208, media card detector 502 may send data to one or more registers 504 associated with alternate programming registers access path 304. In this exemplary design, data is passed to register 504 from media card detector 502 via a path 506. This data may represent that media card 104 has been inserted into socket 102. Media card detector 502 may then pass control to MMC driver 208. By providing commands to programming registers 310 via alternate programming registers access path 304, MMC driver 208 may establish communications with media card 104. By MMC driver 208 interacting with media card 104, software applications 204 may access and use the capabilities of the media card.

If determined that none of the drivers (e.g., SD driver 206, MMC driver 208, etc.) is compatible with inserted media card 104, media card detector 502 may initiate power removal from the inserted media card. Additionally, as power is removed, media card detector 502 may continue to block data representing the insertion of media card 104 from being provided to media card reader 302. Media card detector 502 may also remove power from socket 102 if one of the drivers is compatible with inserted media card 104. For example, media card detector 502 may initiate the removal of power from socket 102 prior to passing control to the compatible software driver (e.g., SD driver 206, MMC driver 208, etc.). Once control is passed to an appropriate software driver, power may be restored.

Path 506 may provide media card detector 502 access to Alternative Programming Registers Access Path 304. Thus, media card detector 502 may access bus interface 300 and/or programming registers 310 via path 506. Alternative Programming Registers Access Path 304 may include decoding logic for mapping additional addresses to programming register 310. To collect information from media card detector 502, Alternative Programming Registers Access Path 304 may include one or more registers (e.g., register 506). For example, media card detector 502 may provide data to register 506 to alert MMC driver 208 that inserted media card 104 may be compatible with the driver. In some embodiments, additional circuitry (e.g., control logic circuitry) may be included in media card controller circuitry 500 so that inserted media card 104 may be controlled by MMC driver 208 without using Alternative Programming Registers Access Path 304.

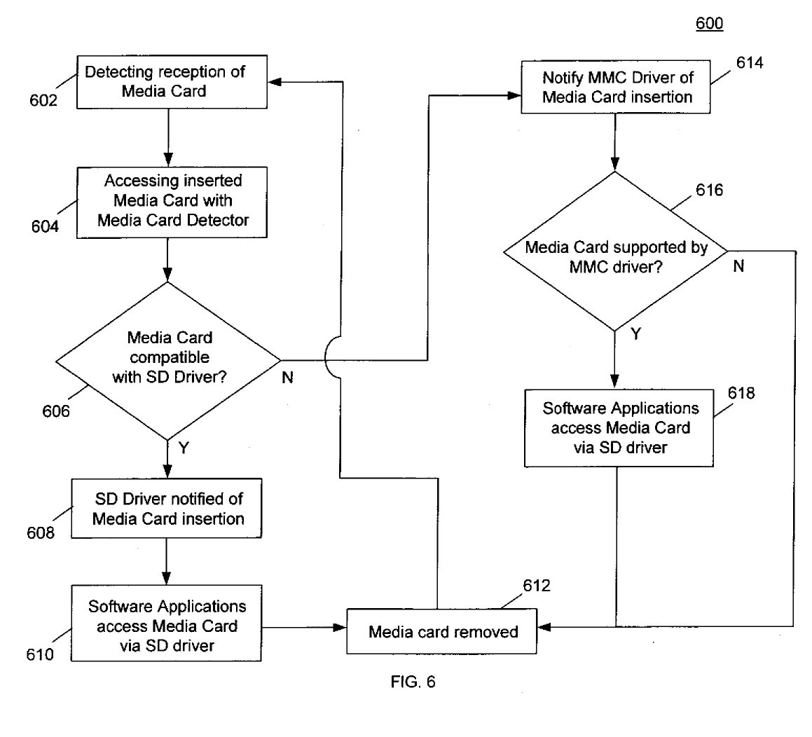

Referring to FIG. 6, a flowchart 600 is shown that represents some of the operations of media card controller circuitry 500. For example, some operations may include media card detector 502 detecting 602 a media card (e.g., media card 104) being inserted into socket 102. Along with detecting the media card insertion, media card detector 502 may provide power to the inserted media card without intervention from software components (e.g., SD driver 206, MMC driver 208, etc.) in software domain 200.

Operations may also include media card detector 502 accessing 604 the inserted media card and attempting to determine the type and/or capabilities of the inserted media card 104. To interrogate the inserted media card, media card detector 502 may exchange data with the media card without intervention from software components such as SD driver 206 and/or MMC driver 208. Along with an absence of software intervention, during the interrogation software components (e.g., SD driver 206, MMC driver 208, etc.) may not be notified of that media card 104 has been inserted.

By accessing and interrogating the inserted media card, media card detector 502 may determine 606 if the inserted card is compatible with SD driver 206. If media card 104 is compatible with SD driver 206, operations of media card controller circuitry 500 may include media card detector 502 notifying 608 SD driver 206 that the inserted media card may be compatible with the SD driver. In some implementations, notification may include media card detector 502 providing data to programming registers 310 so that SD driver 206 may be alerted to the insertion of media card 104 and the potential compatibility. Upon SD driver 206 being notified, operations may include software applications 204 accessing 610 the inserted media card via SD driver 206. Access is typically provided until media card 104 is removed 612 from socket 102. Once removed, power delivery to socket 102 may be halted along with access to media card 104 for software applications 204. Additionally, when media card 104 is removed, operations of media card detector 502 may include returning to detect 602 the insertion of another (or the same) media card.

If the inserted media card is incompatible with SD driver 206, operations may include notifying 614 MMC driver 208 of the insertion of media card 104. In some implementations, notification may include storing data in a register that may be accessed by MMC driver 208. The stored data may represent the insertion of media card 104 into socket 102. In one embodiment, media card detector 502 may store data in register 506 that may represent the insertion of the media card. Additionally, data may be stored that represents that the inserted media card may be compatible with MMC driver 208. In another embodiment, data may be stored one or more other registers such as programming registers 310.

Operations may also include determining 616 if the inserted media card is supported by MMC driver 208. For example, by media card detector 502 determining the card type of the inserted card or capabilities of the card, MMC driver 208 may determine if the card is supportable. If the inserted media card is supportable by MMC driver 208, operations may include MMC driver 208 allowing 618 software applications 204 to access the inserted media card via the MMC driver. MMC driver 208 may access the inserted media card via programming registers 310. In such a scenario, MMC driver 208 may interact with programming registers 310 via Alternate Programming Registers Access Path 504 by using an address assigned to the programming registers. As mentioned above, the address associated with path 504 may be different compared to the address associated with path 316 (used by SD driver 206 to interact with the programming registers). In another embodiment, MMC driver 208 may interact with inserted media card 104 via a dedicated path (not shown in FIG. 5). This dedicated path may include one or more registers and/or circuitry (e.g., logic circuitry, state machine circuitry, etc.) for controlling an inserted media card. Access is typically allowed until the media card is removed 612 from socket 102. If MMC driver 208 determines that the inserted media card is not supportable, access to the media card is not allowed and media card detector 502 waits for the media card to be removed 612 and then returns to detect 602 the insertion of another (or the same) media card.

One or more of the components of hardware domain 202 (shown in FIG. 2) may be implemented in one or more types of architectures. In some embodiments hardware components may be implemented individually and/or in combinations of two or more components. For example, media card controller circuitry 500 may be implemented with one or more general processors (e.g., a microprocessor) and/or by one or more specialized devices (e.g., an application specific integrated circuit (ASIC), etc.). Media card controller circuitry 500 may also be implemented in a single integrated circuit as a monolithic structure or in a distributed structure. Similarly one or more of the components (e.g., media card detector 502) in media card controller circuitry 500 may be implemented as a single integrated circuit as a monolithic structure or in a distributed structure. In some embodiments registers (e.g., programming registers 310, register 506) included media card controller circuitry 500 may reside in a memory (e.g., random access memory (RAM), read-only memory (ROM), static RAM (SRAM), etc.).

One or more of the operations associated with flowchart 400 and/or flowchart 600 may be performed by one or more programmable processors (e.g., a microprocessor, an ASCI, etc.) executing a computer program. The execution of one or more computer programs may include operating on input data (e.g., contents programming registers 310, contents of a media card, etc.) and generating output (e.g., storing data in programming registers 310, etc.). The operations may also be performed by media card controller circuitry 500 and/or included components (e.g., media card detector 502) implemented as special purpose logic circuitry (e.g., an FPGA (field programmable gate array), an ASIC (application-specific integrated circuit), etc.).

In some embodiments, operations of media card controller circuitry 500 (or components included in the media card controller circuitry) may be suitable for executing a computer program and may include, by way of example, general and/or special purpose microprocessors. In general, a processor may receive instructions and data from a memory (e.g., ROM, RAM, etc.). Media card controller circuitry 500 may be operatively coupled to receive data from or transfer data to, or both, one or more mass storage devices (e.g., magnetic, magneto-optical disks, or optical disks, etc.) for storing data. Information carriers suitable for embodying computer program instructions and data may include forms of non-volatile memory, including by way of example semiconductor memory devices, e.g., EPROM, EEPROM, and flash memory devices; magnetic disks, e.g., internal hard disks or removable disks; magneto-optical disks; and CD-ROM and DVD-ROM disks.

Embodiments of media card controller circuitry 500 (or one or more components included in the media card controller circuitry) may be implemented in digital electronic circuitry, or in computer hardware, firmware, software, or in combinations of them. Media card controller circuitry 500 (or one or more components included in the media card controller circuitry) may also be implemented as a computer program product, e.g., a computer program tangibly embodied in an information carrier, e.g., in a machine-readable storage device (e.g., RAM, ROM, hard-drive, CD-ROM, etc.) or in a propagated signal. The computer program product may be executed by or control the operation of, data processing apparatus, e.g., a programmable processor, a computer, or multiple computers. A computer program may be written in one or more forms of programming languages, including compiled or interpreted languages, and it can be deployed in any form, including as a stand-alone program or as a module, component, subroutine, or other unit suitable for use in a computing environment. A computer program may be deployed to be executed on one computing device (e.g., controller, computer system, etc.) or on multiple computing devices (e.g., multiple controllers) at one site or distributed across multiple sites and interconnected by a communication network.

A number of implementations have been described. Nevertheless, it will be understood that various modifications may be made. Accordingly, other implementations are within the scope of the following claims.

What is claimed is:

1. An apparatus, comprising:
a media card reader implemented on an integrated circuit, comprising:
at least one register configured to store data representative of a media card being inserted into a media card socket, wherein the register is accessible, via a first path, by a secure digital (SD) driver for determining compatibility with the SD driver, if the inserted media card is incompatible with the SD driver, the register is accessed via a second path by a multimedia card (MMC) driver for determining compatibility with the MMC driver.

2. The apparatus of claim 1, wherein the first path is associated with a first address.

3. The apparatus of claim 2, wherein the second path is associated with a second address, different from the first address.

4. The apparatus of claim 1, wherein the SD driver exchanges data with the media card to determine compatibility.

5. The apparatus of claim 1, wherein the MMC driver exchanges data with the media card to determine compatibility.

6. The apparatus of claim 1, wherein if the media card is compatible with the SD driver, the SD driver provides a software application access to the media card.

7. The apparatus of claim 1, wherein if the media card is compatible with the MMC driver, the MMC driver provides a software application access to the media card.

8. The apparatus of claim 1, wherein the SD driver stops power delivery to the media card if the SD driver is incompatible with the media card.

9. The apparatus of claim 1, wherein the SD driver halts communicating with the media card if the SD driver is incompatible with the media card.

10. The apparatus of claim 1, wherein the MMC driver stops power delivery to the media card if the MMC driver is incompatible with the media card.

11. The apparatus of claim 1, wherein the media card is an SD card.

12. The apparatus of claim 1, wherein the media card is a secure digital input/output (SDIO) card.

13. The apparatus of claim 1, wherein the media card is an MMC card.

14. An apparatus, comprising:
media card controller circuitry implemented on an integrated circuit, comprising:
a media card detector configured to identify, absent input from software, a type of media card inserted into a media card socket; and
a first register configured to store data representative of the media card type, wherein the register is accessible, via a first path, by a secure digital (SD) driver, the register is also accessible via a second path by a multimedia card (MMC) driver.

15. The apparatus of claim 14, further comprises:
a second register configured to store data representative of the media card being compatible with the MMC driver.

16. The apparatus of claim 15, wherein the second register is accessible via the second path by the MMC driver.

17. The apparatus of claim 14, wherein if the media card is compatible with the SD driver, the media card is accessible by a software application through the SD driver.

18. The apparatus of claim 14, wherein if the media card is compatible with the MMC driver, the media card is accessible by a software application through the MMC driver.

19. The apparatus of claim 14, wherein the first path is associated with a first address.

20. The apparatus of claim 17, wherein the second path is associated with a second address, different from the first address.

21. A method, comprising:
storing data in a register that represents a media card being inserted into a socket;
accessing the register with a first software driver via a first path;
determining if a secure digital (SD) driver is compatible with the media card;
if incompatible with the SD driver, accessing the register with a multimedia driver (MMC) via a second path, different from the first path; and
determining if the MMC driver is compatible with the media card.

22. The method of claim 21, further comprising:
if compatible with the SD driver, allowing an application access to the media card via the SD driver.

23. The method of claim 21, further comprising:
if compatible with the MMC driver, allowing an application access to the media card via the MMC driver.

24. The method of claim 21, wherein the first path is associated with a first address.

25. The method of claim 24, wherein the second path is associated with a second address, different from the first address.

26. An article comprising:
a storage medium storing instructions that when executed by a machine result in the following operations:
storing data in a register that represents a media card being inserted into a socket;
accessing the register with a first driver via a first path;
determining if a secure digital (SD) driver is compatible with the media card;
if incompatible with the SD driver, accessing the register with a multimedia driver (MMC) via a second path, different from the first path; and
determining if the MMC driver is compatible with the media card.

27. The article of claim 26, wherein said instructions that when executed by said machine result in the following additional operations:
if compatible with the SD driver, allowing an application access to the media card via the SD driver.

28. The article of claim 27, wherein said instructions that when executed by said machine result in the following additional operations:
if compatible with the MMC driver, allowing an application access to the media card via the MMC driver.
